(19) United States
(12) Patent Application Publication
(10) Pub. No.: US 2020/0132520 A1
(43) Pub. Date: Apr. 30, 2020

(54) SENSOR AND METHOD OF MANUFACTURING SENSOR

(71) Applicant: SONY CORPORATION, Tokyo (JP)

(72) Inventor: Mao KATSUHARA, Kanagawa (JP)

(73) Assignee: SONY CORPORATION, Tokyo (JP)

(21) Appl. No.: 16/629,273

(22) PCT Filed: Jun. 14, 2018
(86) PCT No.: PCT/JP2018/022731

§ 371 Date: Jan. 7, 2020

(30) Foreign Application Priority Data
Jul. 14, 2017 (JP) 2017-137786

(51) Int. Cl. G01D 11/24; H05K 1/18; H05K 1/02; H05K 3/30

(52) U.S. Cl. CPC G01D 11/245; H05K 1/189; H05K 2201/10151; H05K 3/303; H05K 1/0283

(57) ABSTRACT

A sensor according to an embodiment of the present disclosure includes: a base material; a sensor element placed on the base material; a wiring line electrically coupled to the sensor element; and a stretchable member that covers the sensor element and the wiring line and is bonded to the base material.

### TECHNICAL FIELD

The present disclosure relates to, for example, a sensor including an electronic circuit provided on a base material having a curved surface and stretchability, and a method of manufacturing the same.

### BACKGROUND ART

Recently, wearable devices to be worn on arms or installed in clothes have been developed, but generally, electronic devices and electronic components are hard and each have a rectilinear shape. This makes it uncomfortable to wear the devices and difficult to wear them continuously for a long time. If it is possible to make the electronic devices or the electronic components comfortably fit human bodies, it is possible to wear the electronic devices such as a sensor device to be brought into direct contact with the body for a long time without stress.

In this regard, for example, PTL 1 discloses an electrically-conductive composite yarn whose bendability is increased by winding, around an aluminum foil electrically-conductive fiber spun tight around a core of organic fiber, another type of electrically-conductive yarn. Moreover, for example, PTLs 2 and 3 each disclose a method of printing a circuit directly on fabric using electrically-conductive paste excellent in adhesion to the base material and stability of conductivity.

### CITATION LIST

### Patent Literature

PTL 1: Japanese Unexamined Patent Application Publication No. 2016-61006

PTL 2: Japanese Unexamined Patent Application Publication No. 2015-79656

PTL 3: Japanese Unexamined Patent Application Publication No. 2014-26968

### SUMMARY OF THE INVENTION

Incidentally, various base materials such as, for example, textile, leather, elastomer resin, and the like are used as a basic material in the wearable device. It is therefore required to develop a structure that makes it possible to form a fine electronic circuit pattern regardless of the base material and improve retention and reliability of the formed electronic circuit, as well as a method of manufacturing the same.

It is desired to provide a sensor that makes it possible to form an electronic circuit in the similar method regardless of the type and the shape of the base material and improve retention and reliability of the electronic circuit, as well as a method of manufacturing the sensor.

A sensor according to an embodiment of the present disclosure includes: a base material; a sensor element placed on the base material: a wiring line electrically coupled to the sensor element; and a stretchable member that covers the sensor element and the wiring line and is bonded to the base material.

A method of manufacturing a sensor according to an embodiment of the present disclosure includes placing a sensor element and a wiring line on a base material, and bonding a stretchable member to the base material. The wiring line is electrically coupled to the sensor element. The stretchable member covers the sensor element and the wiring line.

In accordance with the sensor according to an embodiment of the disclosure and the method of manufacturing the sensor according to an embodiment, the sensor element and the wiring line electrically coupled to the sensor element are placed on the base material, and the stretchable member covering them is bonded to the base material. This makes it possible to retain the sensor element and its wiring line on the base material in the similar method regardless of the type and the shape of the base material. Moreover, because the sensor element and the wiring line are retained on the base material by the stretchable member, it is possible to mitigate the load on the sensor element and the wiring line caused by bending and stretching the base material.

In accordance with the sensor according to an embodiment of the disclosure and the method of manufacturing the sensor according to an embodiment, because the sensor element and the wiring line are retained on the base material by bonding the stretchable member to the base material, it is possible to form the electronic circuit on the base material in the similar method regardless of the type and the shape of the base material. The stretchable member covers the sensor element and the wiring line electrically coupled to the sensor element. Moreover, because the sensor element and the wiring line are not fixed directly to the base material, the load of stress applied to the sensor element and the wiring line by bending and stretching the base material is mitigated. This improves reliability of the electronic circuit provided on the base material.

It is to be noted that the effects described here are not necessarily limited, but any of effects described in the present disclosure may be included.

### BRIEF DESCRIPTION OF DRAWING

FIG. 1 is a schematic cross-sectional view of an example of a sensor according to an embodiment of the present disclosure.

FIG. 2 is a schematic plan view of the sensor illustrated in FIG. 1.

FIG. 3A is a schematic cross-sectional view for describing a process of manufacturing the sensor illustrated in FIG. 1.

FIG. 3B is a schematic cross-sectional view that follows FIG. 3A.

FIG. 3C is a schematic cross-sectional view that follows FIG. 3B.

FIG. 4 is a schematic cross-sectional view of an example of a sensor according to Modification Example 1 of the present disclosure.

FIG. 5 is a schematic plan view of an example of a sensor according to Modification Example 2 of the present disclosure.

FIG. 6 is a schematic plan view of another example of the sensor according to Modification Example 2 of the present disclosure.

FIG. 7 is a schematic plan view of another example of a sensor according to Modification Example 3 of the present disclosure.

FIG. 8 is a perspective view of an example of an appearance according to Application Example.

### MODES FOR CARRYING OUT THE INVENTION

The following describes an embodiment of the present disclosure in detail with reference to the drawings. It is to be noted that the following description is a specific example of the present disclosure, but the present disclosure is not limited to the following mode. The description is made in the following order.

1. Embodiment (An example in which an electronic circuit including a sensor element is fixed on a base material using a stretchable member)

### 1-1. Configuration of Sensor

### 1-2. Method of Manufacturing Sensor

### 1-3. Workings and Effects

2. Modification Example 1 (An example in which an electronic circuit including a sensor element is formed on a base material having a three-dimensional shape)
3. Modification Example 2 (An example of a wiring line shape near a sensor element)
4. Modification Example 3 (An example of a peripheral circuit included in a sensor)

### 5. Application Example

### 1. EMBODIMENT

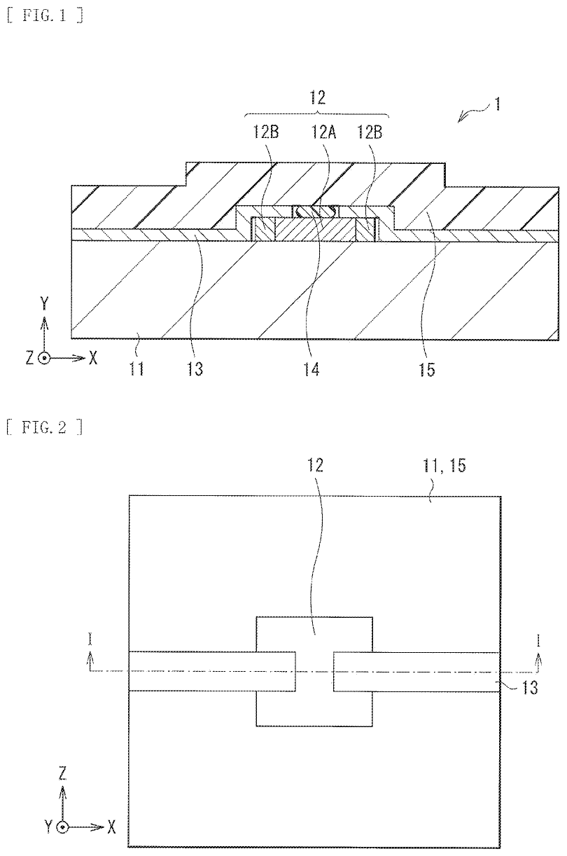

FIG. 1 schematically illustrates a cross-sectional configuration of a sensor (sensor 1) according to an embodiment of the present disclosure. FIG. 2 schematically illustrates a planar configuration of the sensor 1, and the cross section of the sensor 1 illustrated in FIG. 1 corresponds to line I-I in FIG. 2. This sensor 1 is useful when, for example, forming an electronic circuit on a base material having stretchability, such as cloth. The sensor 1 according to the present embodiment has a configuration in which an electronic component (e.g., sensor element 12) included in an electronic circuit and a wiring line 13 electrically coupled to the sensor element 12 are placed on a base material 11 and covered by a stretchable member 15. It is to be noted that FIGS. 1 and 2 schematically illustrate an example of the configuration of the sensor 1, which may be different from actual dimensions and shapes.

### (1-1. Configuration of Sensor)

As described above, the sensor 1 has the configuration in which the sensor element 12 and the wiring line 13 electrically coupled to the sensor element 12 are placed on the base material 11, and the stretchable member 15 covering them retains the sensor element 12 and the wiring line 13 on the base material 11. In the present embodiment, the sensor element 12 and the wiring line 13 themselves are not fixed on the base material 11, but fixed on the stretchable member 15 side bonded to the base material 11.

The base material 11 has stretchability. Specifically, the base material 11 may include, for example, textile such as woven fabric, knitted web (knitted fabric), lace, felt, and nonwoven, or porous resin substrate. As a constituent material of the base material 11, synthetic plastics such as polyester (PEs), polyethylene (PE), nylon, acrylic, polyurethane (PU), and polytetrafluoroethylene (PTFE) are included. In addition, regenerated fiber such as acetate rayon and cupra, natural fiber materials such as cotton, silk, linen, and wool, and any mixed materials thereof are included. Furthermore, for example, silicone rubber, urethane rubber, fluororubber, natural rubber, and acrylic rubber having Young's modulus of 0.1 MPa to 10 MPa, or elastomer such as thermoplastic elastomer, and thermosetting elastomer, leathers such as natural leather, synthetic leather. artificial leather, and the like are included.

Still further, the base material 11 may include a soft resin substrate such as polyethylene terephthalate (PET), polyethylene naphthalate (PEN), polyimide (PI), polyether sulfone (PES), cycloolefin polymer (COP), and polycarbonate (PC).

The sensor element 12 is, for example, a sensor element that obtains biological information and environmental information of the user, such as, for example, a PPG (Photoplethysmography) sensor element. This PPG sensor element includes a light emitter and a photodetector. A biosensor is categorized into two types including a bioelectric potential sensor and an optical sensor, for example. The bioelectric potential sensor makes it possible to detect biological information of the user such as, for example, heart rate information (heart rate), pulse rate information (pulse rate), sweating information, electroencephalogram information (e.g., information about α wave, β wave. θ wave, and δ wave), or galvanic skin response (GSR). The optical sensor makes it possible to detect the biological information of the user such as, for example, pulse rate information (pulse rate), blood flow information (blood flow amount and blood flow velocity), and blood oxygen level. Additionally, the biosensor makes it possible to detect body temperature by using a thermocouple and to detect respiration by using a strain sensor. As specific examples of the sensor element 12 other than those described above, it is possible to use, for example, an atmospheric pressure sensor element, a gas sensor element, a moisture sensor element, an acceleration sensor element, a gyro sensor element, and the like.

The sensor element 12 has an insulator 12A in the middle and an electrode 12B on the peripheral edge of the insulator 12A, for example. The electrode 12B is electrically coupled to the wiring line 13. The sensor element 12 is not fixed to the base material 11, but placed directly on the base material 11, for example, and fixed to the stretchable member 15 side by an adhesive member 14 provided on the insulator 12A, as illustrated in FIG. 1.

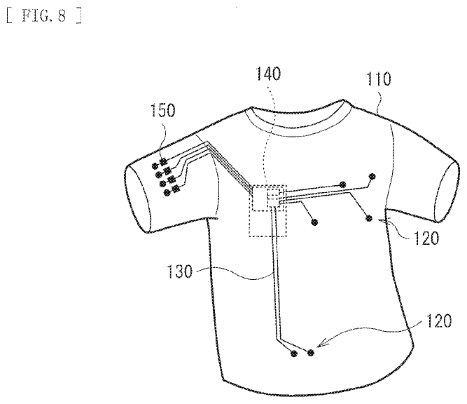

The wiring line 13 is included in the electric circuit together with the sensor element 12, and one end of the wiring line 13 is electrically coupled to the electrode 12B of the sensor element 12 as illustrated in FIG. 1, for example. The sensor element 12 and the wiring line 13 may be coupled to each other on a top surface of the sensor element 12 as illustrated in FIGS. 1 and 2, for example, or may be coupled to each other on a side surface of the sensor element 12. The other end of the wiring line 13 is coupled to, for example, a control section (e.g., control section 140, see FIG. 8) that controls the sensor element 12.

The wiring line 13 may include a common wiring line material, and a portion of the wiring line 13 near the sensor element 12 preferably includes a wiring line material having a stretchability of 10% or higher, for example. As such a wiring line material, an electrically-conductive material is included such as electrically-conductive nanofiber including metal nanoparticle such as gold nanoparticle, silver nanoparticle, copper nanoparticle, and nickel nanoparticle, electrically-conductive paste including carbon nanotube, graphene, carbonna. carbon black, or the like mixed with a resin material, or electrically-conductive polymer such as PEDOT/PSS. The wiring line 13 except the portion near the sensor element 12 may include a metal thin film of gold (Au), silver (Ag), copper (Cu), aluminum (Al), molybdenum (Mo). titanium (Ti), and the like, and a laminated film thereof.

The adhesive member 14 is for temporarily mounting the sensor element 12 on the stretchable member 15 when manufacturing the sensor 1. The adhesive member 14 is, for example, adhesive or glue having an insulating property. Specific materials may be, for example, polyurethane-based adhesive, vinyl acetate-based adhesive, acrylic resin-based adhesive, rubber-based adhesive, epoxy resin-based adhesive, silicone resin-based adhesive, hot-melt adhesive, and the like.

The stretchable member 15 is for retaining the sensor element 12 and the wiring line 13 included in the electronic circuit on the base material 11. The stretchable member 15 preferably has an adhesive property, and preferably includes a film-shaped thermoplastic resin, for example. Examples of a specific thermoplastic resin include polyvinylchloride (PVC), polypropylene (PP), polyurethane (PU), polyacetal (POM), polyamide (PA), and polycarbonate (PC), or copolymer thereof and the like.

### (1-2. Method of Manufacturing Sensor)

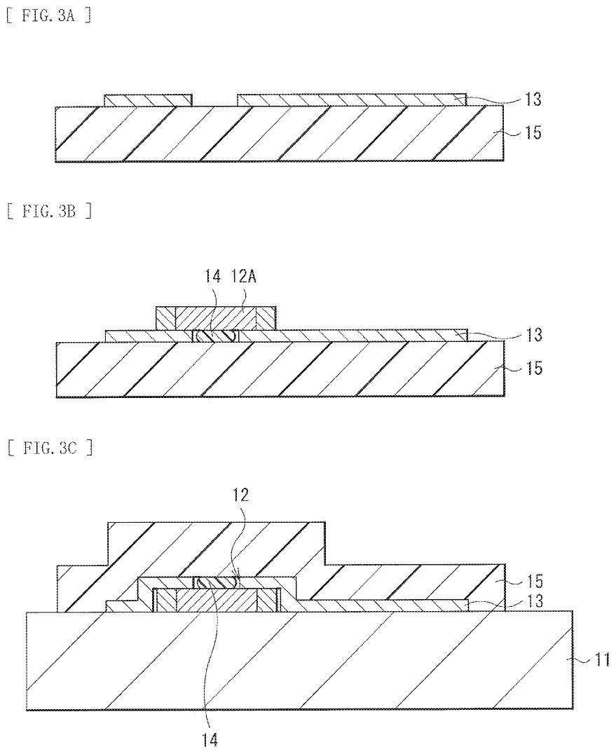

A process of manufacturing the sensor 1 according to the present embodiment is described with reference to FIGS. 3A to 3C. It is to be noted that the manufacturing method described herein is merely an example, and another method may be used for manufacturing the sensor 1.

First, a polyurethane film having a thickness of 150 μm, for example, is prepared as the stretchable member 15, and placed on a supporting substrate (not illustrated). Subsequently, as illustrated in FIG. 3A, the wiring line 13 having a desired pattern is formed on the stretchable member 15 by offset printing, for example, using stretchable silver ink (available from Du Pont), for example. It is to be noted that as the method of forming the wiring line 13, a printing process other than offset printing may be used including, for example, screen printing, inkjet, gravure offset printing, reverse offset printing, flexographic printing, nanoimprint, dispenser, and the like.

Next, as illustrated in FIG. 3B, as the adhesive member 14, for example, polyurethane-based adhesive is applied to the insulator 12A of the sensor element 12, and the sensor element 12 is temporarily mounted on the stretchable member 15. Applying heat to a mounting portion at this time temporarily bonds the stretchable member 15 and the adhesive member 14 to each other. Subsequently, the stretchable member 15 provided with the sensor element 12 and the wiring line 13 is temporarily placed on the base material 11, and a support member is removed. Finally, as illustrated in FIG. 3C, the stretchable member 15 is thermally transferred onto the base material 11 using a vacuum laminator, for example. This bonds the stretchable member 15 to the base material 11, and the stretchable member 15 fixes the sensor element 12 and the wiring line 13 onto the base material 11. The sensor 1 according to the present embodiment is finished in this manner.

It is to be noted that the sensor element 12 and the wiring line 13 may be partially bonded to the stretchable member 15 using electrically-conductive adhesive curable at low temperature, for example. Moreover, when the stretchable member 15 including the sensor element 12 and the wiring line 13 is transferred onto the base material 11, a base layer may be formed on the base material 11 in advance using a thermosetting stretchable resin or the like. This makes it possible to prevent atmospheric air and moisture from degrading the sensor element 12 and the wiring line 13.

### (1-3. Workings and Effects)

As described above, recently, wearable devices to be worn on arms or installed in clothes have been developed. However, generally, electronic devices and electronic components are hard and each have a rectilinear shape. This makes it uncomfortable to wear the devices and difficult to wear them continuously for a long time. Therefore, to enable the wearable device to be worn for a long time without stress, there have been proposed a method of using an electrically-conductive fiber and weave it into clothes and a method of printing a circuit directly onto fabric. However, a technology has not yet been established of freely forming a highly integrated electronic circuit in a wearable device at low cost.

Moreover, various base materials are used as the substrate (basic material) in the wearable device, including a base material having flexibility and stretchability such as clothes, a base material having a three-dimensional shape, and the like. A common circuit forming technology demands technological development depending on the type of the substrate on which a circuit is to be formed. Furthermore, depending on the type of the substrate, stability of roughness and dimensions is poor, which makes it difficult to form a fine wiring line pattern.

From the above, it is required to develop a structure that makes it possible to improve retention and reliability of the electronic circuit regardless of the base material. and a method of manufacturing the same.

In contrast, in the sensor 1 according to the present embodiment, for example, the wiring line 13 and the sensor element 12 are formed in this order on the stretchable member 15 such as a polyurethane film, and these are pressure-bonded onto the base material 11 by thermal transfer. This makes it possible to form the electronic circuit on the base material 11 in the same method regardless of the type and the shape of the base material 11. Moreover, the wiring line 13 and the sensor element 12 included in the electronic circuit are retained on the base material 11 by the stretchable member 15. That is, the wiring line 13 and the sensor element 12 are not fixed directly to the base material 11, and this mitigates stress concentration on the coupling portion of the sensor element 12 and the wiring line 13, for example, caused by stress such as distortion generated when the base material 11 is bent or stretched.

As described above, in the present embodiment, because the sensor element 12 and the wiring line 13 are disposed on the stretchable member 15 side, and these are pressure-bonded onto the base material 11 by thermal transfer, it is possible to form the electronic circuit on the base material 11 in the similar method regardless of the type and the shape of the base material 11. Moreover, the wiring line 13 and the sensor element 12 are retained on the base material 11 by the stretchable member 15, but not fixed directly to the base material 11. Thus, the distortion generated when the base material 11 is bent or stretched is mitigated, which makes it possible to improve reliability of the electronic circuit.

Furthermore, in the present embodiment, because the sensor element 12 and the wiring line 13 are formed on the stretchable member 15 side in advance, it is possible to form a highly fine circuit pattern regardless of the type and the shape of the base material 11. Still further, it is possible to implement the electronic component such as the sensor element 12 on the base material 11 having low heat resistance.

Moreover, the electronic component (e.g., sensor element 12) in the present embodiment is not in close contact with the base material 11 as described above. Thus, it is possible to sense a detection object on a back surface side of the base material 11 by using, for example, a porous substrate or a substrate having pores as the base material 11 and disposing thereon the sensor element 12 such as a PPG sensor, an atmospheric pressure sensor, a gas sensor, a moisture sensor, or a biochemical sensor.

Next, modification examples (Modification Examples 1 to 3) of the present disclosure are described. It is to be noted that components corresponding to those of the sensor 1 according to the above-described embodiment are denoted with the same reference numerals, and descriptions thereof are omitted.

### 2. MODIFICATION EXAMPLE 1

FIG. 4 schematically illustrates a cross-sectional configuration of a sensor (sensor 2) according to Modification Example 1 of the present disclosure. The sensor 2 according to the present modification example uses a three-dimensional structure as a base material 21, in which the electronic component including the sensor element 12 and the wiring line 13 is pressure-bonded onto the base material 21 like this by the stretchable member 15. It is to be noted that FIG. 4 schematically illustrates an example of the configuration of the sensor 2, which may be different from actual dimensions and shapes.

It is possible to manufacture the sensor 2 according to the present modification example in the following manner, for example. First, a polyurethane film having a thickness of 75 μm, for example, is prepared as the stretchable member 15, and placed on a supporting substrate. Subsequently, after a metal laminated film having, for example, a Mo/Al/Mo structure is formed on the stretchable member 15, a desired electrode pattern is formed using laser zapping, for example. Thereafter, the wiring line 13 is formed taking into account its stretchability.

Next, as the sensor element 12, for example, a gas sensor and an electronic circuit component that drives the gas sensor are temporarily mounted using polyurethane-based adhesive (adhesive member 14), for example. Subsequently, the stretchable member 15 provided with the sensor element 12 and the wiring line 13 is thermally pressure-bonded to the base material 21 using the vacuum laminator. The base material 21 is, for example, a spherical polycarbonate molded component, in which an opening 21H is formed in advance. The stretchable member 15 including the sensor element 12 and the wiring line 13 bonds an intake portion of the gas sensor to the opening 21H. The sensor 2 (environmental gas sensor) that is able to sense the detection object on the back surface side of the base material 21 is finished in this manner.

As described above, using the method of manufacturing the sensor (sensor 1 or 2) according to the present disclosure makes it possible to form a highly reliable and high-performance electronic circuit on the base material 11 or 21 at low cost using the same process regardless of the type and the shape of the base material 11 or 21.

### 3. MODIFICATION EXAMPLE 2

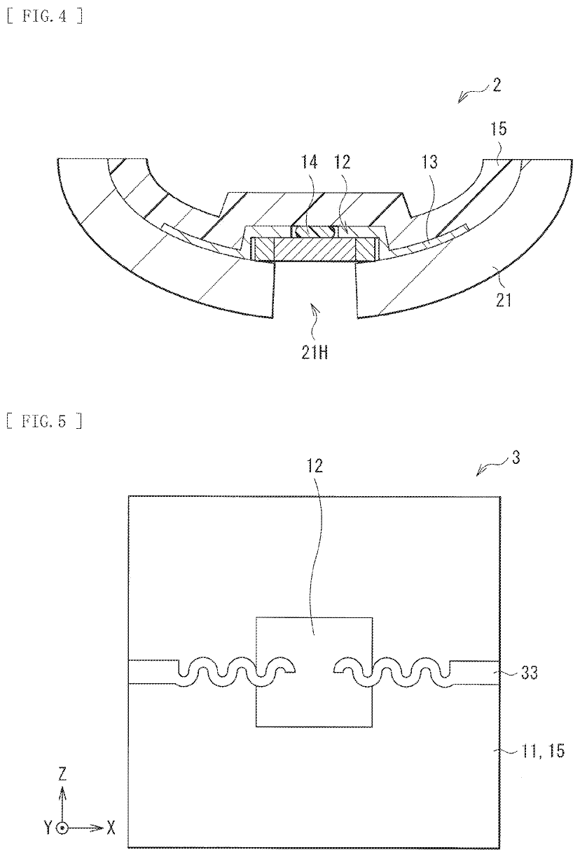

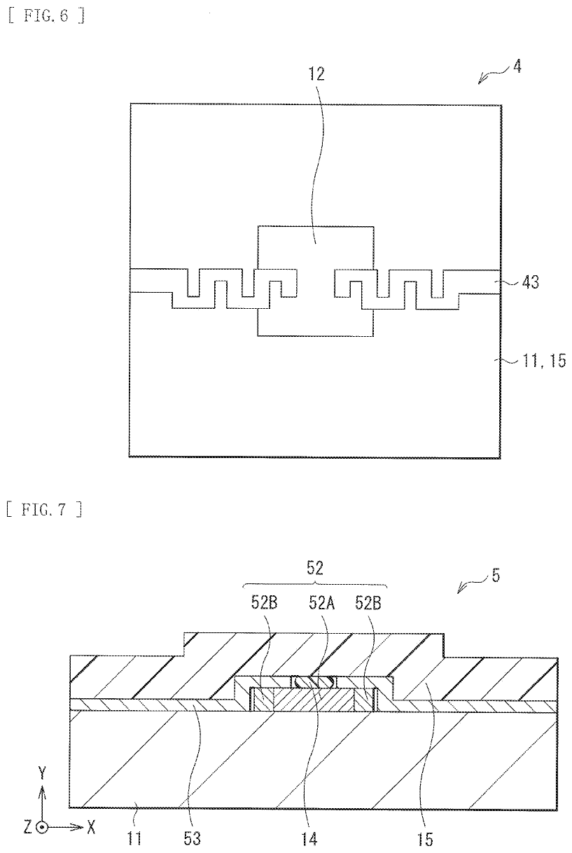

FIG. 5 schematically illustrates an example of a planar configuration of a sensor (sensor 3) according to Modification Example 2 of the present disclosure. The sensor 3 according to the present modification example has a wiring line 33 near the sensor element 12 patterned to wave. In this manner, patterning the wiring line 33 near the sensor element 12 for mechanical stretchability makes it possible to form the wiring line 33 using a common wiring line material including a metal thin film such as gold, silver, copper, aluminum, molybdenum, or titanium, a laminated film thereof, and the like.

Moreover, the pattern of the wiring line 33 near the sensor element 12 is not limited to the waving pattern. For example, like a sensor 4 illustrated in FIG. 6, a wiring line 43 may be formed to meander.

### 4. MODIFICATION EXAMPLE 3

The configurations in the embodiment and Modification Examples 1 and 2 described above are also applicable to a functional element (e.g., amplifier) other than the sensor element included in the sensor and an electronic circuit (e.g., amplification circuit) including the same. FIG. 7 schematically illustrates a cross-sectional configuration of an amplifier 52 as an example of the functional element included in a sensor (sensor 5) according to Modification Example 3 of the present disclosure and a wiring line 53 included in the amplification circuit including the same.

The sensor 5 according to the present modification example includes the amplifier 52 in addition to the sensor element, as described above. The amplifier 52 is electrically coupled to the wiring line 53 included in the amplification circuit. As with the sensor 1 described above, they are opposed on the base material 11, covered by the stretchable member 15, and retained on the base material 11.

The amplifier 52 has an amplifying function for, for example, controlling an operation of an active element using an input signal, and obtaining an output signal having energy higher than that of the input signal. The amplifier 52 and the amplification circuit including the same are used in an oscillation circuit, an arithmetic circuit, and the like that use amplification, for example. Similarly to the sensor element 12 described above, the amplifier 52 has an insulator 52A in the middle and an electrode 52B on the peripheral edge of the insulator 52A, for example. The electrode 52B is electrically coupled to the wiring line 53. The amplifier 52 is not fixed to the base material 11, but placed directly on the base material 11, for example, and fixed to the stretchable member 15 side by an adhesive member 14 provided on the insulator 52A.

The wiring line 53 is included in the amplification circuit together with the amplifier 52, and one end of the wiring line 53 is electrically coupled to the electrode 52B of the amplifier 52 as illustrated in FIG. 7, for example. The amplifier 52 and the wiring line 53 may be coupled to each other on a top surface of the amplifier 52 or may be coupled to each other on a side surface of the amplifier 52. The other end of the wiring line 53 is coupled to, for example, a control section (e.g., control section 140, see FIG. 8) that controls the amplifier 52. Moreover, as illustrated in FIGS. 5 and 6, the wiring line 53 near the amplifier 52 may be formed in a pattern such as a waving pattern or a meandering pattern for mechanical stretchability.

In the present modification example, the above-described configuration makes it possible to improve reliability of the electronic circuit (peripheral circuit) including the functional element other than the sensor element 12.

It is to be noted that, although the amplifier 52 is described as the functional element included in the sensor in the present modification example, it is not limitative. Examples of the functional element included in the sensor include, in addition to the amplifier, a semiconductor element such as a microcomputer, a resistor, a capacitor, an inductor, and a transistor diode, and the like. It is to be noted that the present technology is also applicable to, for example, an electrocardiogram sensor and an electromyogram sensor in which the sensor element itself includes an electrode alone. That is, the present technology is applicable to all functional elements included in the above-described sensors.

### 5. APPLICATION EXAMPLE

Next, Application Example of an electronic device including the sensors 1 to 5 described in the embodiment and Modification Examples 1 to 3 described above is described. However, a configuration of a wearable device described below is merely an example, and the configuration thereof is changeable as appropriate.

FIG. 8 illustrates an appearance of a garment 110. This garment 110 includes various sensor elements 120 that detect or measure sweating, body temperature, sweat component, epidermal gas, blood glucose, and the like, for example, as the sensor element 12, a control section 140 that controls the sensor elements 120, and a wiring line 130 that couples the sensor elements 120 and the control section 140. Each sensor element 120 obtains information (user information) about an action or physical condition of the user wearing the garment 110. and supplies the information to the control section 140. for example. It is to be noted that a circuit 150 may be provided in the middle of the wiring line 130 between the sensor element 120 and the control section 140. In the garment 110, for example, the sensor element 120 and the wiring line 130 include the sensor 1 (or sensors 2 to 5) described above.

It is to be noted that the sensors 1 to 5 and the method of manufacturing the same in the present disclosure are applicable to a portion of a clothing ornament such as, for example, a watch (wrist watch), a bag, a hat, glasses, and shoes in addition to the garment 110 described above as a wearable device, and the type thereof is not particularly limited. They are also applicable to an electronic device other than the wearable device.

Although the disclosure has been described above with reference to the embodiment and Modification Examples 1 to 3, the disclosure is not limited to the modes described in the above-described embodiment and the like, but may be modified in a variety of ways. For example, the components described in the above-described embodiment and the like do not have to be all included, but other components may be further included. Moreover, the materials and thickness of the components described above are merely examples and the materials and thickness are not limited to those described.

It is to be noted that the effects described in the present specification are merely examples, but not limited. Moreover, other effects may be included.

It is to be noted that the present disclosure may also include the following configuration.

(1)

A sensor including:

a base material;

a sensor element placed on the base material:

a wiring line electrically coupled to the sensor element: and

a stretchable member that covers the sensor element and the wiring line and is bonded to the base material.

(2)

The sensor according to (1), in which the sensor element is placed directly on the base material.

(3)

The sensor according to (1) or (2), in which the sensor element is fixed to the base material by the stretchable member.

(4)

The sensor according to any of (1) to (3), in which one end of the wiring line is coupled on a top surface of the sensor element.

(5)

The sensor according to any of (1) to (4), in which the wiring line has a stretchability of 10% or higher.

(6)

The sensor according to any of (1) to (5), in which the wiring line includes an electrically-conductive material having stretchability.

(7)

The sensor according to any of (1) to (6), in which the wiring line is patterned to wave or meander near the sensor element.

(8)

The sensor according to any of (1) to (7), in which

the wiring line is included in a peripheral circuit including a functional element, and

one end of the wiring line included in the peripheral circuit is coupled on a top surface of the functional element.

(9)

The sensor according to (8), in which the wiring line included in the peripheral circuit is patterned to wave or meander near the functional element.

(10)

The sensor according to any of (1) to (9), in which the stretchable member includes a thermoplastic film.

(11)

The sensor according to any of (1) to (10), in which the base material has stretchability or flexibility.

(12)

The sensor according to any of (1) to (11). in which the base material includes a three-dimensional structure.

(13)

A method of manufacturing a sensor, the method including placing a sensor element and a wiring line on a base material, and bonding a stretchable member to the base material, the wiring line being electrically coupled to the sensor element, the stretchable member covering the sensor element and the wiring line.

(14)

The method of manufacturing the sensor according to (13), in which the sensor element is temporarily mounted on the stretchable member after the wiring line is formed on the stretchable member.

(15)

The method of manufacturing the sensor according to (14). in which the sensor element and the wiring line provided on the stretchable member are thermally transferred onto the base material.

This application claims the priority on the basis of Japanese Patent Application No. 2017-137786 filed with Japan Patent Office on Jul. 14, 2017, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A sensor comprising:
a base material;
a sensor element placed on the base material;
a wiring line electrically coupled to the sensor element; and
a stretchable member that covers the sensor element and the wiring line and is bonded to the base material.

2. The sensor according to claim 1, wherein the sensor element is placed directly on the base material.

3. The sensor according to claim 1, wherein the sensor element is fixed to the base material by the stretchable member.

4. The sensor according to claim 1, wherein one end of the wiring line is coupled on a top surface of the sensor element.

5. The sensor according to claim 1, wherein the wiring line has a stretchability of 10% or higher.

6. The sensor according to claim 1, wherein the wiring line includes an electrically-conductive material having stretchability.

7. The sensor according to claim 1, wherein the wiring line is patterned to wave or meander near the sensor element.

8. The sensor according to claim 1, wherein
the wiring line is included in a peripheral circuit including a functional element, and
one end of the wiring line included in the peripheral circuit is coupled on a top surface of the functional element.

9. The sensor according to claim 8, wherein the wiring line included in the peripheral circuit is patterned to wave or meander near the functional element.

10. The sensor according to claim 1, wherein the stretchable member comprises a thermoplastic film.

11. The sensor according to claim 1, wherein the base material has stretchability or flexibility.

12. The sensor according to claim 1, wherein the base material comprises a three-dimensional structure.

13. A method of manufacturing a sensor, the method comprising
placing a sensor element and a wiring line on a base material, and bonding a stretchable member to the base material, the wiring line being electrically coupled to the sensor element, the stretchable member covering the sensor element and the wiring line.

14. The method of manufacturing the sensor according to claim 13, wherein the sensor element is temporarily mounted on the stretchable member after the wiring line is formed on the stretchable member.

15. The method of manufacturing the sensor according to claim 14, wherein the sensor element and the wiring line provided on the stretchable member are thermally transferred onto the base material.
